(19) United States
(12) Patent Application Publication
(10) Pub. No.: US 2021/0063459 A1
(43) Pub. Date: Mar. 4, 2021

(54) APPARATUS AND METHOD FOR ANALYZING CAUSE OF FAILURE DUE TO DIELECTRIC BREAKDOWN ON BASIS OF BIG DATA

(71) Applicants: Hyundai Motor Company, Seoul (KR); Kia Motors Corporation, Seoul (KR)

(72) Inventor: Hyun Soo Park, Seoul (KR)

(21) Appl. No.: 16/860,694

(22) Filed: Apr. 28, 2020

(30) Foreign Application Priority Data
Aug. 30, 2019 (KR) 10-2019-0107338
Oct. 23, 2019 (KR) 10-2019-0131821

(51) Int. Cl. G01R 31/00; G06F 16/23; G01R 31/12

(52) U.S. Cl. CPC G01R 31/007; G01R 31/1272; G06F 16/2379

(57) ABSTRACT

An apparatus and a method for analyzing a cause of a failure due to a dielectric breakdown based on big data are provided. A failure cause factor data set, a normal state data set, or a state recovery data set is generated and transmitted to a big data server when a dielectric resistance value is measured to be a minimum normal value or less. A cause of a failure is analyzed by receiving data corresponding to the data sets from the big data server, calculating influence indexes for failure cause factors, and selecting a failure cause factor based on the basis of the influence indexes.

### CROSS-REFERENCE TO RELATED APPLICATION

This application claims the priority benefit of Korean Patent Application Nos. 10-2019-0107338, filed on Aug. 30, 2019 and 10-2019-0131821, filed on Oct. 23, 2019, the disclosure of which is incorporated herein by reference.

### BACKGROUND

### 1. Field of the Disclosure

The present disclosure relates to a system and a method for determining a failure using a dielectric resistance value of a vehicle that is periodically collected and analyzing a cause of the failure, and more particularly to an apparatus and a method for analyzing a cause of a failure due to a dielectric breakdown based on big data.

### 2. Description of the Prior Art

According to a conventional failure cause analyzing method, when a specific device of a vehicle is introduced into a service center after a failure occurs in the device, the device may be repaired by analyzing a cause of the failure only when a failure situation occurs again in the vehicle. Further, since a plurality of devices as well as the corresponding device have to be demounted and disassembled to analyze a cause of a failure in a situation in which the same failure state occurs again, time and costs for analyzing the cause of the failure and repairing the device are increased. Further, when a cause of a failure is not accurately identified in a situation in which the failed device is a main component of the vehicle, all the components have to be replaced, causing a wrong repair or an unnecessary repair.

### SUMMARY

The present disclosure provides an apparatus and a method for analyzing a cause of a failure due to a dielectric breakdown based on big data, by which a cause of a failure may be more accurately recognized when a failure symptom occurs intermittently by analyzing travel information and dielectric resistance value data collected through sensors attached to a vehicle, calculating influence indexes for predicted failure cause factors, and selecting a failure cause factor through relative magnitudes of the influence indexes or an influence index calculation cumulative number of a reference or more.

According to an exemplary embodiment, an apparatus for analyzing a cause of a failure due to a dielectric breakdown on the basis of big data may include a resistance value monitoring unit configured to monitor whether a dielectric resistance value of a vehicle is decreased to a minimum normal value or less, a data set generating unit configured to set a failure state section and a normal state section according to a preset reference when the dielectric resistance value is a minimum normal value or less, and generate a failure cause factor data set and a normal state data set including a plurality of failure cause factor data for the failure state section and the normal state section, a data set transmitting/receiving unit configured to transmit the generated data set to a big data server, and receive data that corresponds to the data set from the big data server, an influence index calculating unit configured to calculate influence indexes for failure cause factors using the received data, and a result information generating unit configured to generate analysis result information by selecting a failure cause factor based on the calculated influence indexes.

The apparatus may further include an analysis result output unit configured to output the analysis result information to a user. The data set generating unit may be configured to set a section from a time point at which the dielectric resistance value is measured to a preset time to a failure state section when the dielectric resistance value is the minimum normal value or less, and may be configured to set a section from a start time point of the failure state section to a preset time to a normal state section.

The resistance value monitoring unit may be configured to monitor whether the dielectric resistance value received after the failure state section is recovered to the minimum normal value or greater, the data set generating unit may be configured to generate a recovery time point data set including a plurality of failure cause factor data for the state recovery section by, when the dielectric resistance value reaches the minimum normal value or greater again, set a section from a time point at which the dielectric resistance value reaches the minimum normal value to a preset time to a state recovery section, and the data set transmitting/receiving unit may be configured to transmit the generated recovery time point data set to the big data server, and receive the data corresponding to the data set from the big data server.

Additionally, the result information generating unit may be configured to select a failure cause factor by reflecting the calculated influence indexes and a cumulative number according to the influence indexes. The influence index calculating unit may be configured to periodically receive the failure state data set and the recovery state data set, and calculate the influence indexes for the failure cause factors using data that corresponds to the failure state data set and the recovery state data set, which have been received, and the result information generating unit may be configured to select the failure cause factor based on the calculated influence indexes and reflect the selected failure cause factor on the analysis result information.

The result information generating unit may be configured to generate a failure cause factor analysis table according to the analysis result whenever the measured dielectric resistance value of the vehicle is the minimum normal value or less and it is determined that a failure state is generated. The failure cause factor analysis table may include at least one of information for determining relative magnitudes of the calculated influence indexes and influences, failure cause factor doubt information, and cause factor doubt selection cumulative number information.

According to an exemplary embodiment, when the influence indexes are a preset value or less, the result information generating unit may be configured to determine that it is impossible to determine an influence and does not add a number to the cumulative number. In particular, the analysis result information may include a reliability value, and the reliability value increases as the cumulative number increases and decreases as the cumulative number decreases. The minimum normal value may be about 1000 kΩ. Further, the apparatus may include a big data server configured to receive a data set from the data set transmitting/receiving unit, extract the data corresponding to the data set, and transmit the extracted data to the data set transmitting/receiving unit.

According to an exemplary embodiment, a method for analyzing a cause of a failure due to a dielectric breakdown on the basis of big data may include monitoring whether a dielectric resistance value of a vehicle is decreased to a minimum normal value or less, setting a failure state section and a normal state section according to a preset reference when the dielectric resistance value is a minimum normal value or less, and generating a failure cause factor data set and a normal state data set including a plurality of failure cause factor data for the failure state section and the normal state, transmitting the generated data set to a big data server, and receiving data that corresponds to the data set from the big data server, calculating influence indexes for failure cause factors using the received data, and generating analysis result information by selecting a failure cause factor based on the calculated influence indexes.

The method may further include outputting the analysis result information to a user. The generating of the data set may include setting a section from a time point at which the dielectric resistance value is measured to a preset time to a failure state section when the dielectric resistance value is the minimum normal value or less, and setting a section from a start time point of the failure state section to a preset time to a normal state section.

Additionally, the method may include monitoring whether the dielectric resistance value received after the failure state section reaches the minimum normal value or greater, generating a recovery time point data set including a plurality of failure cause factor data for the state recovery section by, when the dielectric resistance value reaches the minimum normal value or greater again, setting a section from a time point at which the dielectric resistance value reaches the minimum normal value to a preset time to a state recovery section, and transmitting the generated recovery time point data set to the big data server, and receiving the data that corresponds to the data set from the big data server.

According to an exemplary embodiment, the generating of the analysis result information may include selecting a failure cause factor by reflecting the calculated influence indexes and a cumulative number according to the influence indexes. The failure state data set and the recovery state data set may be received periodically, and the influence indexes for the failure cause factors may be calculated using data that corresponds to the failure state data set and the recovery state data set, which have been received, and the failure cause factor may be selected based on the calculated influence indexes the selected failure cause factor may be reflected on the analysis result information.

Further, the generating of the analysis result information may include generating a failure cause factor analysis table according to the analysis result whenever the measured dielectric resistance value of the vehicle is the minimum normal value or less and it is determined that a failure state is generated. The failure cause factor analysis table may include at least one of information for determining relative magnitudes of the calculated influence indexes and influences, failure cause factor doubt information, and cause factor doubt selection cumulative number information.

According to an exemplary embodiment, in the generating of the analysis result information, when the influence indexes are a preset value or less, it may be determined that it is impossible to determine an influence and does not add a number to the cumulative number. In the generating of the analysis result information, the analysis result information may include a reliability value, and the reliability value increases as the cumulative number increases and decreases as the cumulative number decreases. According to an embodiment, the minimum normal value may be about 1000 kΩ.

The method may further include receiving the data set, extracting the data that corresponds to the data set, and transmitting the extracted data, by the big data server. According to the present disclosure, numerical data of devices may be extracted even when a failure symptom occurs intermittently by analyzing travel information including a dielectric resistance value of a vehicle and selecting a failure cause factor, time and costs consumed for an inspection and a repair when a failure symptom occurs may be saved by analyzing the numerical data and selecting the failure cause factor, and a wrong repair or an unnecessary repair may be prevented.

### BRIEF DESCRIPTION OF THE DRAWINGS

The above and other aspects, features and advantages of the present disclosure will be more apparent from the following detailed description taken in conjunction with the accompanying drawings, in which:

FIG. 1 is a diagram of an apparatus for analyzing a cause of a failure due to a dielectric breakdown on the basis of big data according to an exemplary embodiment of the present disclosure;

FIG. 2 is a diagram of an apparatus for analyzing a cause of a failure due to a dielectric breakdown on the basis of big data according to an exemplary embodiment of the present disclosure;

FIG. 3 is a view illustrating a failure state section and a normal state section which are set when a dielectric resistance value is a minimum normal value or less according to an exemplary embodiment of the present disclosure;

FIG. 4 is a view illustrating a failure state section, a normal state section, and a recovery state section, which are set when a dielectric resistance value is a minimum normal value or less and in turn becomes the minimum normal value or more according to an exemplary embodiment of the present disclosure;

FIG. 5 is a view illustrating a flow of data when a dielectric resistance value is a minimum normal value or less and in turn is recovered to the minimum normal value or more in an exemplary embodiment of the present disclosure, in which a recovery cause factor is selected and is reflected on analysis result information;

FIG. 6 is a view illustrating a data set generated according to an exemplary embodiment of the present disclosure;

FIG. 7 is a flowchart illustrating a process of calculating influence indexes for failure cause factors according to an exemplary embodiment of the present disclosure;

FIG. 8 is a view illustrating a plurality of failure cause factor analysis tables generated whenever a failure symptom occurs to calculate influence indexes for failure cause factors according to an exemplary embodiment of the present disclosure;

FIG. 9 is a view illustrating analysis result information actually generated by an apparatus for analyzing a cause of a failure, which uses travel information including a dielectric resistance value according to an exemplary embodiment of the present disclosure; and

FIG. 10 is a flowchart of a method for analyzing a cause of a failure due to a dielectric breakdown on the basis of big data according to an exemplary embodiment of the present disclosure.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor. The memory is configured to store the modules and the processor is specifically configured to execute said modules to perform one or more processes which are described further below.

Furthermore, control logic of the present disclosure may be embodied as non-transitory computer readable media on a computer readable medium containing executable program instructions executed by a processor, controller/control unit or the like. Examples of the computer readable mediums include, but are not limited to, ROM, RAM, compact disc (CD)-ROMs, magnetic tapes, floppy disks, flash drives, smart cards and optical data storage devices. The computer readable recording medium can also be distributed in network coupled computer systems so that the computer readable media is stored and executed in a distributed fashion, e.g., by a telematics server or a Controller Area Network (CAN).

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

Hereinafter, exemplary embodiments of the present disclosure will be described in more detail with reference to the accompanying drawings so as to allow those skilled in the art to easily implement the present disclosure. However, the present disclosure may be implemented in various different forms and is not limited to exemplary embodiments described herein.

Further, parts irrelevant to the present disclosure are omitted in the drawings to make the present disclosure clear and the same reference numerals are designated to the same or similar components throughout the specification. Throughout the specification, when it is described that a part includes an element, it may mean that the part may further include second element without excluding the second element unless a contradictory description is made.

Hereinafter, an apparatus and a method for analyzing a cause of a failure due to a dielectric breakdown based on big data according to an exemplary embodiment of the present disclosure will be described with reference to the drawings.

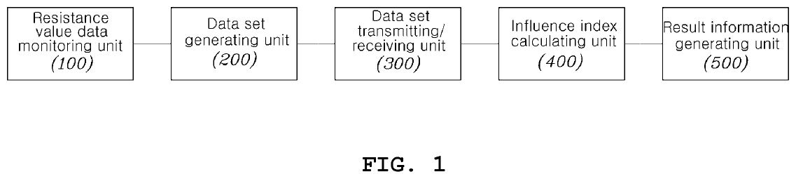

FIG. 1 is a diagram of an apparatus for analyzing a cause of a failure due to a dielectric breakdown based on big data according to an exemplary embodiment of the present disclosure. Referring to FIG. 1, the apparatus for analyzing a cause of a failure due to a dielectric breakdown based on big data according to the exemplary embodiment of the present disclosure may include a resistance value monitoring unit 100, a data set generating unit 200, a data set transmitting/receiving unit 300, an influence index calculating unit 400, and a result information generating unit 500. Each of the units may be operated by a controller having a memory and a processor configured to execute the processes of the units.

Particularly, the resistance value monitoring unit 100 may be configured to monitor whether a dielectric resistance value of a vehicle is decreased to a minimum normal value or less. The resistance value monitoring unit 100 may be configured to periodically collect a dielectric resistance value by using a sensor attached to a vehicle, and continuously monitor whether the collected dielectric resistance value is decreased to the minimum normal value or less. The dielectric resistance value may be received while being contained in travel information of the vehicle, and may be received separately.

The travel information may refer to arithmetic numerical data acquired by a substantial number of parts included in the vehicle, and according to an exemplary embodiment of the present disclosure, may refer to the temperature of a motor, the revolutions per minute (RPM) of the motor, the output of a heater, the RPM of an air conditioner compressor, and the like, and the present disclosure is not limited thereto but any numerical data measured using sensors and other instruments for measurement may be used without limitation.

According to an exemplary embodiment of the present disclosure, when the dielectric resistance value is the minimum normal value or less, a symptom of a failure may be determined to be generated, and the data set generating unit 200 may be requested to generate a failure cause factor data set and a normal state data set including a plurality of failure cause factor data to analyze a cause of the failure. In particular, the minimum normal value may refer to a resistance value of a small value (e.g., a lowest limit) by which the state of the vehicle may be determined to be normal.

The minimum normal value may be about 1000 kΩ, and it may be determined that a dielectric breakdown failure is generated in response to determining that the dielectric resistance value is about 300 kΩ or less, and it may be determined that the step is a preliminary failure step in response to determining that the dielectric resistance value is about 300 kΩ to 1000 kΩ and a failure cause analyzing process of the present disclosure may be performed. When the measured dielectric resistance value is decreased to about 1000 kΩ or less, it may be determined that a failure occurs and the state is not a normal state, and a failure state section and a normal state section are set to analyze the cause, and a failure cause factor data set and a normal state data set including a plurality of failure cause factor data for the failure state section and the normal state section may be generated.

According to an exemplary embodiment of the present disclosure, the equipment numerical data monitoring unit 100 may be configured to monitor whether the equipment numerical data value received after the failure state section reaches a preset reference range again. When the equipment numerical data value received after the failure state section reaches a preset normal state value again, it may be determined that a normal state is recovered, and a section from a time point at which the normal state value is reached to a preset time may be set to a state recovery section and the data set generating unit 200 may be requested to generate a recover time point data set including a plurality of failure cause factor data for the state recovery section.

The data set generating unit 200 may be configured to set a failure state section and a normal state section according to a preset reference when the dielectric resistance value is a minimum normal value or less, and generate a failure cause factor data set including a plurality of failure cause factor data for the failure state section and the normal state section and a normal state data set. When the dielectric resistance value is the minimum normal value or less in the monitoring result of the resistance value monitoring unit 100, the data set generating unit 200 may be configured to determine that a failure symptom occurs, and set a failure state section and a normal state section according to a preset reference to analyze a cause of the failure.

According to the exemplary embodiment, after the failure state section and the normal state section are set, a failure cause factor data set and a normal state data set including a plurality of failure cause factor data for a failure state section and a normal state section may be generated. In particular, the data set may be generated in a form of a data table including, among various pieces of information included in the travel information during the corresponding section, data items, by which the cause of the failure may be analyzed, but the present disclosure is not limited thereto, and any data set, by which data for inferring a factor that causes a failure may be delivered, may be used without limitation.

Further, an average RPM of a motor in a section, an average RPM of a generator in a section, a change inclination of the RPM of an air conditioner compressor, average power of a high-voltage heater (PTC), an average output of a low direct current-direct current converter (LDC), and an average speed of the vehicle may be present in the data set as data items, and may be formed in a form of a data table. The data set generating unit 200 may be configured to set a section from a time point at which the dielectric resistance value is measured to be the minimum normal value or less to a preset time to a failure state section.

In addition, according to the exemplary embodiment, a section from a start point of the failure state section to a preset time may be set to a normal state section. According to the exemplary embodiment, the data set generating unit 200 may be configured to set a section from a time point at which the dielectric resistance value is measured to be the minimum normal value or less to the preset time to a failure state section, and may be configured to set a section from a start time point of the failure state section to a preset time to a normal state section.

When the dielectric resistance value received after the failure state section reaches a preset reference range again, the data set generating unit 200 may be configured to set a section from a time point at which the minimum resistance value is reached to a preset time to a state recovery section when the dielectric resistance value reaches the minimum resistance value again. The data set generating unit 200 may be configured to generate a recovery time point data set including a plurality of failure cause factor data for the state recovery section.

When a period of time for measuring an dielectric resistance is x seconds in setting a normal state section, a failure state section, and a recovery section, respectively, the failure state section from the dielectric resistance failure time point may be x second before the time point of the dielectric resistance abnormality, the normal state section may be 2x seconds before the x seconds, and the recovery state section may be x seconds before the dielectric resistance recovery time point.

The data set transmitting/receiving unit 300 may be configured to transmit the generated data set to a big data server, and receive the data that corresponds to the data set from the big data server. Additionally, the data set transmitting/receiving unit 300 may be configured to transmit the generated recovery time point data set to the big data server, and receive the data that corresponds to the data set from the big data server. The data set may be received in a form of a data table, and here, the data table may refer to a data form including numerical data for a plurality of failure cause factors but the present disclosure is not limited thereto.

According to an exemplary embodiment of the present disclosure, at least one of the data set of the failure state section, the normal state section, and the state recovery section, which have been generated, may be transmitted to the big data server, and the big data server may be configured to generate the data matched with the corresponding data set in a form of a data table and transmit the generated data to the data set transmitting/receiving unit 300 again. The data set transmitting/receiving unit 300 may be configured to transmit the generated recovery section data set to the big data server.

The influence index calculating unit 400 may be configured to calculate influence indexes for the failure cause factors using the received data. In particular, the influence index calculating unit 400 may be configured to calculate influence indexes by comparing the numerical data of the failure state section and the normal state section for the same failure cause factor. The influence index calculating unit 400 may be configured to calculate the influence index using Equation 1.

factor(influence index)=y/x Equation 1

wherein y is numerical data of a failure cause factor in a normal state section and x is numerical data of a failure cause factor in a failure state section.

According to the exemplary embodiment, it can be considered that as the influence index becomes far away from 1, the influence index is relatively large. The influence index calculating unit 400 may be configured to periodically receive a failure state data set and a recovery state data set, and calculate influence indexes for recovery cause factors using data corresponding to the recovery state data set and the failure state data set, which have been received.

The influence index calculating unit 400 may be configured to calculate the influence index, on which the data of the recovery state section is reflected, using Equation 2.

factor(influence index)=y/x Equation 2

wherein y is numerical data of a failure cause factor in a failure state section and x is numerical data of a failure cause factor in a recovery state section.

According to the exemplary embodiment, it may be considered that as the influence index becomes far away from 1, the influence index is relatively large. The influence index calculating unit 400 may be configured to calculate influence indexes using an influence index calculating process similar to the case in which the numerical data of the failure cause factor in the failure state section is used even when the numerical data of the failure cause factor in the recovery state section is used in calculating the influence indexes.

Additionally, the influence index calculating unit 400 may be configured to periodically receive a failure state data set and a recovery state data set, and calculate influence indexes for failure cause factors using data that corresponds to the failure state data set and the recovery state data set, which have been received. The result information generating unit 500 may be configured to generate analysis result information by selecting a failure cause factor based on the calculated influence indexes.

According to an exemplary embodiment of the present disclosure, the result information generating unit 500 may be configured to calculate the influence indexes using Equations 1 and 2 for the failure cause factors, and determine whether the influences for the failures are relatively small or large by comparing the calculated influence indexes. Additionally, result information may be generated by comparing the influence indexes calculated for the failure cause factors and selecting, among them, the failure cause factor having the largest influence index as a failure cause.

According to another exemplary embodiment of the present disclosure, result information may be generated by selecting, among the influence indexes calculated for the failure cause factors, the failure cause factor having a preset value or greater as a failure cause. When the dielectric resistance is abnormal, the corresponding failure cause factor may be selected as a cause of the failure or may be reflected as the cumulative number when the influence index is calculated with a conclusion that a change of about 5% or more occurs.

The result information generating unit 500 may be configured to select a failure cause factor by reflecting the calculated influence indexes and the cumulative number according to the influence indexes. According to an exemplary embodiment of the present disclosure, it may be considered that as the cumulative number increases, the possibility of the corresponding part being a failure cause factor increases, and as the cumulative number decreases, the accuracy relatively decreases. Additionally, in the case of 10 times or more, a reliability of 100% may be set.

When the magnitude of the influence index of a specific failure cause factor is a predetermined value or less, it may be determined that it is impossible to determine an influence and the cumulative number may not be counted. In particular, when the influence index is greater than about 0.95 and less than about 1.05, it may be determined that it is impossible to determine the influence and the cumulative number may not be counted.

The result information generating unit 500 may be configured to calculate the final degree of influence by reflecting the calculated influence indexes and the cumulative number according to the influence indexes, and the final degree of influence may be calculated using Equation 3.

final degree of influence=abs(1−factor)*cumulative number Equation 3

wherein, factor=influence index

The result information generating unit 500 may be configured to generate a failure cause factor analysis table according to an analysis result whenever the dielectric resistance value of the vehicle is measured to be the minimum normal value or less and it is determined that a failure state is generated. The failure cause factor analysis table may include at least one of the calculated influence indexes and information for determining the relative magnitude of the influence, failure cause factor doubt information, and cause factor doubt selection cumulative number information.

Further, the result information generating unit 500 may be configured to determine that it is impossible to determine an influence when the influence index is a preset value or less, and may not add the number of times to the cumulative number. The analysis result information may include a reliability value, and the reliability value may increase as the cumulative number increases and may decrease as the cumulative number decreases.

The apparatus for analyzing a cause of a failure due to a dielectric breakdown based on big data may further include a big data server configured to receive data set from the data set transmitting/receiving unit, extract data that corresponds to the data set, and transmit the extracted data to the data set transmitting/receiving unit. The big data server may be configured to continuously receive a dielectric resistance value and travel information from the vehicle and store the dielectric resistance and the travel information and may be configured to process and return the travel information, in which the data for the data item included in the data set requested by the apparatus for analyzing a cause of a failure are stored, but the present disclosure is not limited thereto. In other words, and the big data server may be configured to transmit raw data for extracting a data item included in the data set to the apparatus for analyzing a cause of a failure such that the data themselves may be processed by the apparatus for analyzing a cause of a failure.

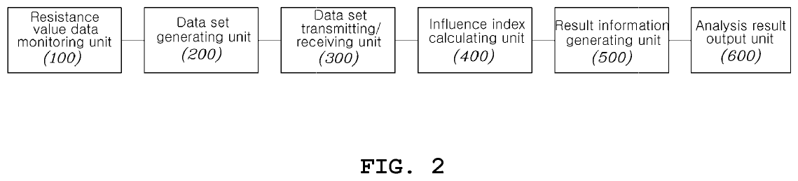

FIG. 2 is a diagram of an apparatus for analyzing a cause of a failure due to a dielectric breakdown based on big data according to another exemplary embodiment of the present disclosure. Referring to FIG. 2, the apparatus for analyzing a cause of a failure due to a dielectric breakdown based on big data according to the exemplary embodiment of the present disclosure may further include an analysis result output unit 600, in addition to the elements of the apparatus for analyzing a cause of a failure due to a dielectric breakdown based on big data according to the first exemplary embodiment.

Particularly, analysis result output unit 600 may be configured to output analysis result information generated by the result information generating unit 500 to the user. According to an exemplary embodiment of the present disclosure, the analysis result output unit 600 may be connected to a display installed within the vehicle and may be configured to transmit the analysis result information to the display and output the analysis result information to the user, but the present disclosure is not limited thereto and any device, such as a speaker, capable of outputting information to the user may be used without limitation.

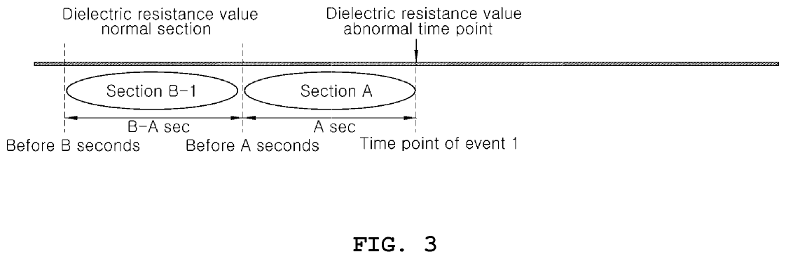

FIG. 3 is a view illustrating a failure state section and a normal state section which are set when a dielectric resistance value is a minimum normal value or less according to an exemplary embodiment of the present disclosure. Referring to FIG. 3, according to an exemplary embodiment of the present disclosure, a failure state section (A) and a normal state section (B-1) which are set when the dielectric resistance value is the minimum normal value or less are illustrated, and a section from a time point at which the equipment numerical data value is measured to a preset time may be set to the failure state section (A) and a section from a start time point in the failure state section to a preset time may be set to a normal state section (B-1).

According to an exemplary embodiment of the present disclosure, the minimum normal value may be about 1000 kΩ, and in the exemplary embodiment, when the periodically collected dielectric resistance value is about 1000 kΩ, a failure state section and a normal state section may be set, and a failure cause factor data set and a normal state data set including a plurality of failure cause factor data may be generated.

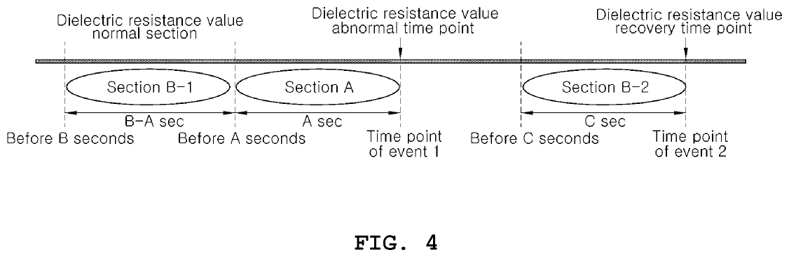

FIG. 4 is a view illustrating a failure state section, a normal state section, and a recovery state section, which are set when a dielectric resistance value is a minimum normal value or less and in turn becomes the minimum normal value or more according to an exemplary embodiment of the present disclosure. Referring to FIG. 4, according to an exemplary embodiment of the present disclosure, a failure state section (A), a normal state section (B-1), and a recovery state section (B-2) which are set when the dielectric resistance value is the minimum normal value or less and in turn becomes the minimum normal value or more are illustrated, and a section from a time point at which the minimum normal value or more is reached to a preset time may be set to the recovery state section (B-2).

According to an exemplary embodiment of the present disclosure, the minimum normal value may be about 1000 kΩ, and in the exemplary embodiment, when the periodically collected dielectric resistance value is decreased to about 1000 kΩ or less and in turn is recovered to about 1000 kΩ or more, a failure state section and a recovery state section may be set, and a failure cause factor data set and a recovery state data set including a plurality of failure cause factor data may be generated.

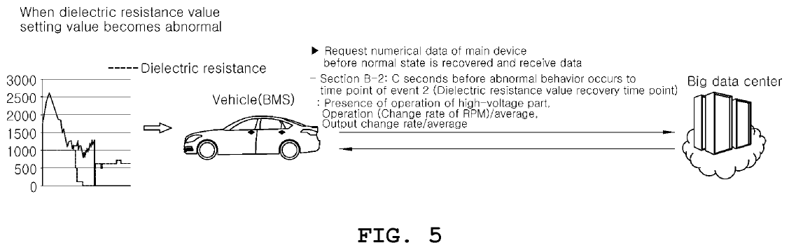

FIG. 5 is a view illustrating a flow of data when a dielectric resistance value is a minimum normal value or less and in turn is recovered to the minimum normal value or more in an exemplary embodiment of the present disclosure, in which a recovery cause factor is selected and is reflected on analysis result information. Referring to FIG. 5, a flow of data when the device value data beyond a reference value range in an exemplary embodiment in which a recovery cause factor is selected and is reflected on the analysis result information is illustrated.

According to an exemplary embodiment of the present disclosure, When the dielectric resistance value is measured to be the minimum normal value or less, and in turn is recovered to the minimum normal value or greater and returns from a normal state to a failure state and then a recovery state in the monitoring result of the dielectric resistance value, a failure cause factor data set including a plurality of failure cause factor data for the failure state section, the normal state section, and the state recovery section may be transmitted to the big data server. Further, according to the exemplary embodiment, the data corresponding to the data set received from the big data server may be transmitted to the apparatus for analyzing a cause of a failure.

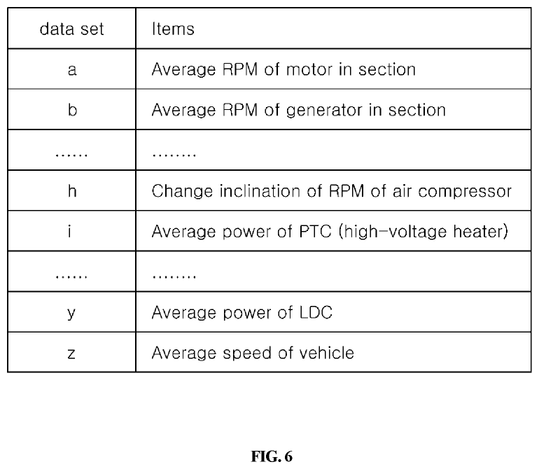

FIG. 6 is a view illustrating a data set generated according to an exemplary embodiment of the present disclosure. Referring to FIG. 6, according to an exemplary embodiment of the present disclosure, data set may be generated in a form of a data catalog that has a preset failure cause factor as an item as in FIG. 6.

The failure cause factor may include an average RPM of a motor in a particular section, an average RPM of a generator in a particular section, a change inclination of an air conditioner compressor, average power of a PTC, average power of an LDC, and an average speed of the vehicle. The present disclosure is not limited thereto, and any factor, by which a cause of a failure that may influence a change of the dielectric resistance value may be analyzed, may be used without limitation.

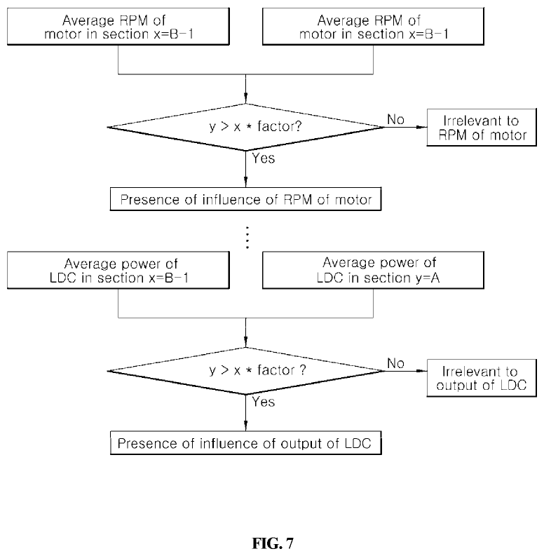

FIG. 7 is a flowchart illustrating a process of calculating influence indexes for failure cause factors according to an exemplary embodiment of the present disclosure. Referring to FIG. 7, according to an exemplary embodiment of the present disclosure, influence indexes may be calculated using Equations 1 or 2 using data for failure cause factors in a failure state section and a normal state section or the failure state section and a state recovery section, and the magnitudes of the influences due to the failure may be compared by comparing the influence indexes of the other failure cause factors.

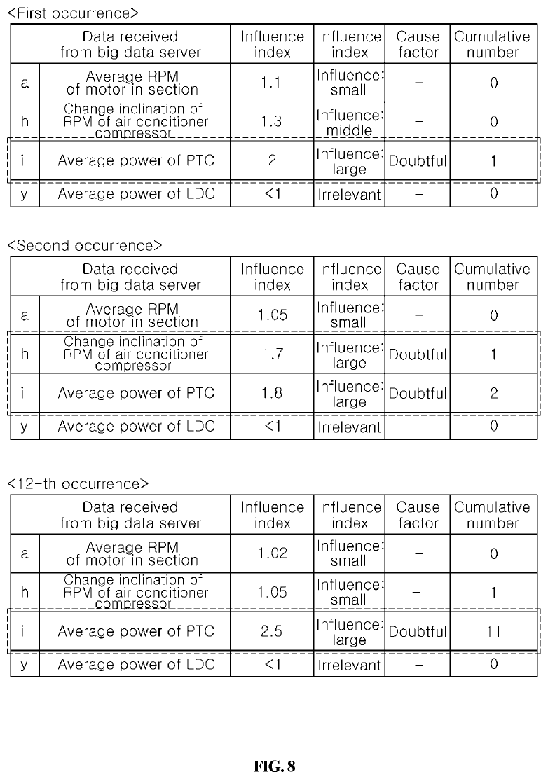

FIG. 8 is a view illustrating a plurality of failure cause factor analysis tables generated whenever a failure symptom occurs to calculate influence indexes for failure cause factors according to an exemplary embodiment of the present disclosure. Referring to FIG. 8, according to an exemplary embodiment of the present disclosure, a plurality of failure cause factor analysis tables generated whenever a failure symptom occurs to calculate influence indexes for failure cause factors are illustrated.

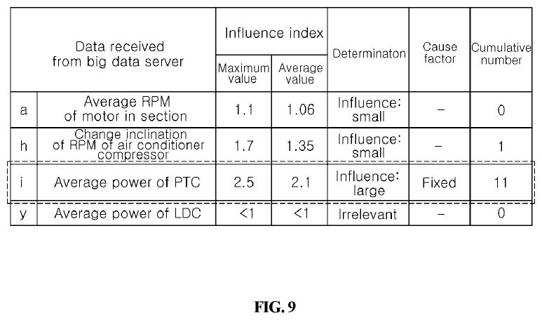

Referring to FIG. 9, according to an exemplary embodiment of the present disclosure, a failure cause factor analysis table that is generated by the number of generated failure states if the result information generating unit 500 determines that the dielectric resistance value is measured to be the minimum normal value or less and a failure state is generated. Each of the failure cause factor analysis tables may include information for determining the relative magnitude of the influence through the calculated influence indexes, a doubt, a fixation, or no cause factor may be expressed as a cause factor, and information regarding a cumulative number according to an influence index, that is, a cause factor doubt selection cumulative number may be generated and included.

When the influence index is a preset value or less, it may be determined that it is impossible to determine an influence, and the preset value may be changed and set according to a failure item, the model of the vehicle, and the like. Accordingly, a misjudgment due to a measurement error or a calculation error may be prevented, and an overfitting may be minimized. Since it is impossible to determine an influence when the cumulative number or the influence index is a preset value or less, the number of times may not be added.

FIG. 9 is a view illustrating analysis result information actually generated by an apparatus for analyzing a cause of a failure, which uses travel information including a dielectric resistance value according to an exemplary embodiment of the present disclosure. Referring to FIG. 9, analysis result information generated by selecting a failure cause factor by using the failure cause factor analysis result table and the failure cause factor analysis result table as in FIGS. 8 and 9 generated when an actual dielectric resistance value is monitored and is measured to be the minimum normal value or less is illustrated. The analysis result information may include a reliability value, and the reliability value may increase as the cumulative number increases and may decrease as the cumulative number decreases.

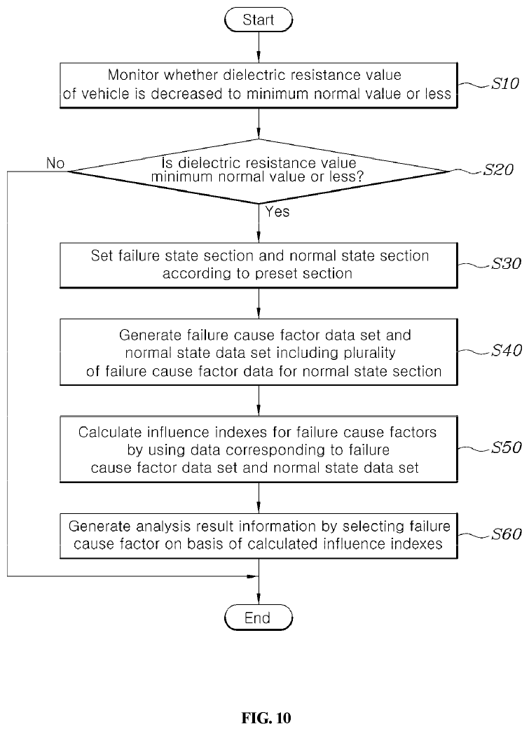

FIG. 10 is a flowchart of a method for analyzing a cause of a failure due to a dielectric breakdown based on big data according to an exemplary embodiment of the present disclosure. The method described herein below may be executed by a controller. In particular, the controller may be configured to monitor whether a dielectric resistance value of a vehicle is decreased to a minimum normal value or less (S10). In particular, the controller may be configured to monitor whether a dielectric resistance value of a vehicle is decreased to a minimum normal value or less. A dielectric resistance value may be periodically collected using a sensor attached to a vehicle, and the controller may be configured to continuously monitor whether the collected dielectric resistance value is decreased to the minimum normal value or less.

The dielectric resistance value may be received while being contained in travel information of the vehicle, and may be separately received. In particular, the travel information may refer to arithmetic numerical data acquired by a substantial number of parts included in the vehicle, and according to an exemplary embodiment of the present disclosure, may refer to the temperature of a motor, the RPM of the motor, the output of a heater, the RPM of an air conditioner compressor, and the like. However, the present disclosure is not limited thereto but any numerical data measured through sensors and other instruments for measurement may be used without limitation.

The controller may be configured to determine whether the dielectric resistance value is a minimum normal value or less (S20). According to an exemplary embodiment of the present disclosure, the controller may be configured to determine that a failure symptom occurs in response to determining the dielectric resistance value is the minimum normal value or less. Particularly, the minimum normal value may refer to a resistance value of a small value (e.g., a lower limit) by which the state of the vehicle may be determined to be normal.

The minimum normal value may be about 1000 kΩ, and when the dielectric resistance value is decreased to about 1000 kΩ or less, the controller may be configured to determine that the state is not a normal state but a failure state. In response to determining that the dielectric resistance value is beyond a preset reference range, a failure state section and a normal state section may be set according to a preset reference (S30). When the measured dielectric resistance value is decreased to about 1000 kΩ or less, the controller may be configured to determine that a failure occurs and the state is not a normal state, and a failure state section and a normal state section may be set to analyze the cause of the failure, and a failure cause factor data set and a normal state data set including a plurality of failure cause factor data for the failure state section and the normal state section.

Additionally, when the dielectric resistance value received after the failure state section reaches the minimum normal value again, the controller may be configured to determine that a normal state is recovered, and a section from a time point at which the normal state value is reached to a preset time may be set to a state recovery section and a recover time point data set may be requested to be generated including a plurality of failure cause factor data for the state recovery section. A failure state section and a normal state section may be set according to a preset reference when the dielectric resistance value is a minimum normal value or less, and a failure cause factor data set may be generated including a plurality of failure cause factor data for the failure state section and the normal state section and a normal state data set.

According to an exemplary embodiment of the present disclosure, a failure state section or a normal state section may be set according to a preset reference when the dielectric resistance value is a minimum normal value or less, and a failure cause factor data set and a normal state data set may be generated including a plurality of failure cause factor data for the failure state section or the normal state section. When the dielectric resistance value is the minimum normal value or less, the controller may be configured to detect that a failure symptom occurs, and a failure state section and a normal state section may be set according to a preset reference to analyze a cause of the failure.

After the failure state section and the normal state section are set, a failure cause factor data set and a normal state data set including a plurality of failure cause factor data for a failure state section and a normal state section may be generated. In particular, the data set may be generated in a form of a data table including, among various pieces of information included in the travel information during the corresponding section, data items, by which the cause of the failure may be analyzed. However, the present disclosure is not limited thereto, and any data set, by which data for inferring a factor that causes a failure may be delivered, may be used without limitation.

Further, an average RPM of a motor in a section, an average RPM of a generator in a section, a change inclination of the RPM of an air conditioner compressor, average power of a high-voltage heater (PTC), an average output of an LDC, and an average speed of the vehicle may be present in the data set as data items, and may be formed in a form of a data table. A section from a time point at which the dielectric resistance value is measured to be the minimum normal value or less to the preset time may be set to a failure state section.

Further, according to the exemplary embodiment, a section from a start point of the failure state section to a preset time may be set to a normal state section. A section from a time point at which the dielectric resistance value is measured to be the minimum normal value or less to the preset time may be set to a failure state section, and a section from a start time point of the failure state section to a preset time may be set to a normal state section.

When the dielectric resistance value received after the failure state section reaches a preset reference range again, a section from a time point at which the minimum resistance value is reached to a preset time may be set to a state recovery section when the dielectric resistance value reaches the minimum resistance value or more again. A recovery time point data set including a plurality of failure cause factor data for the state recovery section may be generated.

A failure cause factor data set and a normal state data set including a plurality of failure cause factor data for the normal state section may be generated (S40). The generated data set may be transmitted to a big data server, and the data that corresponds to the data set may be received from the big data server. Additionally, the generated recovery time point data set to the big data server may be transmitted, and the data corresponding to the data set from the big data server may be received.

According to an exemplary embodiment of the present disclosure, the data set may be received in a form of a data table, and here, the data table may refer to a data form including numerical data for a plurality of failure cause factors but the present disclosure is not limited thereto. At least one of the data set of the failure state section, the normal state section, and the state recovery section, which have been generated, may be transmitted to the big data server, and the big data server may be configured to generate the data matched with the corresponding data set in a form of a data table and may be configured to transmit the generated data to the apparatus for analyzing a cause of a failure.

The generated recovery section data set may be transmitted to the big data server. Influence indexes for failure cause factors may be calculated using data corresponding to the failure cause factor data set and the normal state data set (S50). The influence indexes for the failure cause factors may be calculated using the received data. Additionally, influence indexes may be calculated by comparing the numerical data of the failure state section and the normal state section for the same failure cause factor. In particular, the influence index may be calculated through Equation 1. It may be considered that as the influence index becomes far away from 1, the influence index increases.

According to an exemplary embodiment of the present disclosure, a failure state data set and a recovery set data set may be received periodically, and influence indexes for recovery cause factors may be calculated using data that corresponds to the recovery state data set and the failure state data set, which have been received. The influence index, on which the data of the recovery state section are reflected, may be calculated through Equation 2. It may be considered that as the influence index becomes far away from 1, the influence index increases.

Further, influence indexes may be calculated using an influence index calculating process similar to the case in which the numerical data of the failure cause factor in the failure state section is used even when the numerical data of the failure cause factor in the recovery state section is used in calculating the influence indexes. A failure state data set and a recovery set data set may be received periodically, and influence indexes for recovery cause factors may be calculated using data that corresponds to the recovery state data set and the failure state data set, which have been received.

Analysis result information may be generated by selecting a failure cause factor based on the calculated influence indexes (S60). Particularly, the analysis result information may be generated by selecting a failure cause factor based on the calculated influence indexes. The influence indexes may be calculated using Equations 1 and 2 for the failure cause factors, and the controller may be configured to determine whether the influences for the failures are relatively small or large by comparing the calculating influence indexes.

Result information may be generated by comparing the influence indexes calculated for the failure cause factors and among them, the failure cause factor having the largest influence index may be selected as a failure cause. In particular, result information may be generated by selecting, among the influence indexes calculated for the failure cause factors, the failure cause factor having a preset value or greater as a failure cause. A failure cause factor may be selected by reflecting the calculated influence indexes and a cumulative number according to the calculated influence indexes.

Additionally, a failure cause factor analysis table may be generated according to an analysis result whenever the dielectric resistance value of the vehicle is measured to be the minimum normal value or less and it is determined that a failure state is generated. The failure cause factor analysis table may include at least one of the calculated influence indexes and information for determining the relative magnitude of the influence, failure cause factor doubt information, and cause factor doubt selection cumulative number information.

According to an exemplary embodiment of the present disclosure, because it is impossible to determine an influence when the influence index is a preset value or less, the number of times may not be added to the cumulative number. The analysis result information may include a reliability value, and the reliability value may increase as the cumulative number increases and may decrease as the cumulative number decreases. The big data server may be configured to receive a data set from the apparatus for analyzing a cause of a failure due to a dielectric breakdown based on big data, and may be configured to extract data that corresponds to the data set and transmit the extracted data to the apparatus for analyzing a cause of a failure.

Further, the big data server may be configured to continuously receive a dielectric resistance value and travel information from the vehicle and store the dielectric resistance and the travel information and may be configured to process and return the travel information, in which the data for the data item included in the data set requested by the apparatus for analyzing a cause of a failure. However, the present disclosure is not limited thereto, and the big data server may be configured to transmit raw data for extracting a data item included in the data set to the apparatus for analyzing a cause of a failure such that the data themselves may be processed by the apparatus for analyzing a cause of a failure.

According to an exemplary embodiment of the present disclosure, the generated analysis result information may be output to the user. Additionally, the analysis result output unit may be connected to a display installed within the vehicle and may be configured to transmit the analysis result information to the display and output the analysis result information to the user. However, the present disclosure is not limited thereto and any device, such as a speaker, capable of outputting information to the user may be used without limitation.

What is claimed is:

1. An apparatus for analyzing a cause of a failure due to a dielectric breakdown based on big data, comprising:
a memory configured to store program instructions; and
a processor configured to execute the program instructions, the program instructions when executed configured to:
monitor whether a dielectric resistance value of a vehicle is decreased to a minimum normal value or less;
set a failure state section and a normal state section based on a preset reference in response to determining that the dielectric resistance value is a minimum normal value or less, and generate a failure cause factor data set and a normal state data set including a plurality of failure cause factor data for the failure state section and the normal state section;
transmit the generated data set to a big data server, and receive data corresponding to the data set from the big data server;
calculate influence indexes for failure cause factors using the received data; and
generate analysis result information by selecting a failure cause factor based on the calculated influence indexes.

2. The apparatus of claim 1, wherein the program instructions when executed are configured to set a section from a time point at which the dielectric resistance value is measured to a preset time to a failure state section in response to determining that the dielectric resistance value is the minimum normal value or less, and set a section from a start time point of the failure state section to a preset time to a normal state section.

3. The apparatus of claim 1, wherein the program instructions when executed are configured to:
monitor whether the dielectric resistance value received after the failure state section is recovered to the minimum normal value or greater,
generate a recovery time point data set include a plurality of failure cause factor data for the state recovery section by, in response to determining that the dielectric resistance value reaches the minimum normal value or greater again, setting a section from a time point at which the dielectric resistance value reaches the minimum normal value to a preset time to a state recovery section, and
transmit the generated recovery time point data set to the big data server, and receive the data corresponding to the data set from the big data server.

4. The apparatus of claim 1, wherein the program instructions when executed are configured to select a failure cause factor by reflecting the calculated influence indexes and a cumulative number according to the influence indexes.

5. The apparatus of claim 3, wherein the program instructions when executed are configured to:
periodically receive the failure state data set and the recovery state data set, and calculate the influence indexes for the failure cause factors using data corresponding to the failure state data set and the recovery state data set, which have been received; and
select the failure cause factor based on the calculated influence indexes and reflect the selected failure cause factor on the analysis result information.

6. The apparatus of claim 1, wherein the program instructions when executed are configured to generate a failure cause factor analysis table according to the analysis result whenever the measured dielectric resistance value of the vehicle is the minimum normal value or less and in response to determining that a failure state is generated.

7. The apparatus of claim 6, wherein the failure cause factor analysis table includes at least one of information for determining relative magnitudes of the calculated influence indexes and influences, failure cause factor doubt information, and cause factor doubt selection cumulative number information.

8. The apparatus of claim 1, wherein when the influence indexes are a preset value or less, the program instructions when executed are configured to determine that it is impossible to determine an influence and not add a number to the cumulative number.

9. The apparatus of claim 1, wherein the analysis result information includes a reliability value, and the reliability value increases as the cumulative number increases and decreases as the cumulative number decreases.

10. The apparatus of claim 1, wherein the big data server is configured to receive a data set, extract the data corresponding to the data set, and transmit the extracted data to the processor.

11. A method for analyzing a cause of a failure due to a dielectric breakdown on the basis of big data, comprising:
monitoring, by a processor, whether a dielectric resistance value of a vehicle is decreased to a minimum normal value or less;
setting, by the processor, a failure state section and a normal state section according to a preset reference in response to determining that the dielectric resistance value is a minimum normal value or less, and generating a failure cause factor data set and a normal state data set including a plurality of failure cause factor data for the failure state section and the normal state section;
transmitting, by the processor, the generated data set to a big data server, and receiving data corresponding to the data set from the big data server;
calculating, by the processor, influence indexes for failure cause factors using the received data; and
generating, by the processor, analysis result information by selecting a failure cause factor based on the calculated influence indexes.

12. The method of claim 11, wherein the generating of the data set includes:
setting, by the processor, a section from a time point at which the dielectric resistance value is measured to a preset time to a failure state section in response to determining that the dielectric resistance value is the minimum normal value or less, and setting a section from a start time point of the failure state section to a preset time to a normal state section.

13. The method of claim 11, further comprising:
monitoring, by the processor, whether the dielectric resistance value received after the failure state section reaches the minimum normal value or more;
generating, by the processor, a recovery time point data set including a plurality of failure cause factor data for the state recovery section by, in response to determining that the dielectric resistance value reaches the minimum normal value or more again, setting a section from a time point at which the dielectric resistance value reaches the minimum normal value to a preset time to a state recovery section; and
transmitting, by the processor, the generated recovery time point data set to the big data server, and receiving the data corresponding to the data set from the big data server.

14. The method of claim 11, wherein the generating of the analysis result information includes:
selecting, by the processor, a failure cause factor by reflecting the calculated influence indexes and a cumulative number according to the influence indexes.

15. The method of claim 13, further comprising:
periodically receiving, by the processor, the failure state data set and the recovery state data set, and calculating the influence indexes for the failure cause factors by using data corresponding to the failure state data set and the recovery state data set, which have been received; and
selecting, by the processor, the failure cause factor based on the calculated influence indexes and reflecting the selected failure cause factor on the analysis result information.

16. The method of claim 11, wherein the generating of the analysis result information includes:
generating, by the processor, a failure cause factor analysis table according to the analysis result whenever the measured dielectric resistance value of the vehicle is the minimum normal value or less and it is determined that a failure state is generated.

17. The method of claim 16, wherein the failure cause factor analysis table includes at least one of information for determining relative magnitudes of the calculated influence indexes and influences, failure cause factor doubt information, and cause factor doubt selection cumulative number information.

18. The method of claim 11, wherein in the generating of the analysis result information, when the influence indexes are a preset value or less, it is determined that it is impossible to determine an influence and a number is not added to the cumulative number.

19. The method of claim 11, wherein in the generating of the analysis result information, the analysis result information includes a reliability value, and the reliability value increases as the cumulative number increases and decreases as the cumulative number decreases.

20. The method of claim 11, further comprising:
transmitting, by the processor, the data set to the big data server;
receiving, by the processor, extracted data corresponding to the data set from the big data server.
